(19) United States
(12) Patent Application Publication
(10) Pub. No.: US 2026/0059824 A1
(43) Pub. Date: Feb. 26, 2026

(54) MANUFACTURING METHOD FOR NI FRONTSIDE SIC OHMIC CONTACT

(71) Applicant: Infineon Technologies AG, Neubiberg (DE)

(72) Inventor: Mark HARRISON, Wernberg (AT)

(21) Appl. No.: 19/304,286

(22) Filed: Aug. 19, 2025

(30) Foreign Application Priority Data
Aug. 20, 2024 (DE) 102024207895.6

(51) Int. Cl. H01L 21/04; C23C 14/18; C23C 14/34; C23C 14/58; H01L 21/02

(52) U.S. Cl. CPC H01L 21/0485; C23C 14/18; C23C 14/34; C23C 14/5806; C23C 14/5813; H01L 21/02068

(57) ABSTRACT

The present description relates to a method of manufacturing a silicon carbide wafer comprising forming a semiconductor substrate comprising SiC at a surface or at least specific parts of the surface thereof; cleaning a surface area of the substrate by a hydrogen plasma atmosphere; applying nickel metal contact material on the cleaned surface area to form SiC/Ni metal stacks at the surface of or at least parts of the SiC substrate; and annealing the SiC/Ni metal stacks to form Ohmic contacts at the interface between the SiC and the nickel metal.

### RELATED APPLICATION

This application claims priority to German Patent Application No. 102024207895.6, filed on Aug. 20, 2024, entitled “MANUFACTURING METHOD FOR NI FRONTSIDE SIC OHMIC CONTACT”, which is incorporated by reference herein in its entirety.

### TECHNICAL FIELD

The present disclosure generally relates to methods of manufacturing a silicon carbide (SiC) wafer, especially those comprising a silicon carbide semiconductor substrate surface in contact with a nickel metal contact layer for generating a Ni frontside Ohmic contact.

### BACKGROUND

Semiconductor devices based on silicon carbide (SiC) and similar semiconductor components are widely used in a lot of microelectronic devices. Those microelectronic devices with SiC semiconductor material are used in power applications, high temperature applications, high frequency applications, among others. Many device types based on SiC material comprise integrated circuits that are formed on semiconductor wafers by depositing many types of thin films of material to form the integrated circuits.

Semiconductor devices are coupled to external circuits through frontside and backside contacts. Forming frontside contacts with low resistance is one of the challenges with integrated circuits especially as package dimensions are scaled down. In order to realize an Ohmic contact it is known to use a silicidation reaction by depositing a contact metal, such as sputtered or deposited NiAl material layers, on a SiC surface of a substrate, followed by a thermal annealing processing. The wafer is usually heated to a temperature high enough for resulting in a thin molten surface layer. In this molten state, a silicidation reaction takes place at the interface between the SiC and the deposited metal. The Al component used in the current processes is considered to be responsible for good diode p contacts with acceptable low resistance, but usually leads to reliability issues because Al, O, and C can be found in mixed layers on top of NiSi contact layers after the annealing step.

Therefore, it is an objective of the present application to overcome at least some of the foregoing problems. More particularly, one object is to improve the reliability issues while providing a good Ohmic contact at a frontside or backside, especially a frontside, of a SiC wafer.

### SUMMARY

According to an embodiment, the method of manufacturing a SiC wafer may comprise forming or providing a semiconductor substrate comprising SiC at a surface or at least specific parts of the surface thereof, cleaning a surface area of the substrate by a hydrogen plasma atmosphere, applying nickel metal contact material on the cleaned surface area to form SiC/Ni metal stacks at the surface of or at least parts of the SiC substrate.

Forming or providing a semiconductor substrate may include the formation of integrated circuits at or within the surface area of the semiconductor substrate by depositing of thin films of various materials and by processing those into integrated circuit structures, e.g. by chemical etching processes or the like. In most processes, contaminations in particulate or layer form on or at the surface of the SiC substrate are generated by chemical or physical processes. Those contaminants may be at least partly removed from the surface area to be contacted with the metal contact material by cleaning the surface area of the SiC substrate before the forming of the metal contact layer. Generally, any chemical or physical process may be used, such as a wet chemical etching and/or a plasma processing. According to an embodiment, those contaminants may be cleaned off from the surface by using at least a hydrogen plasma processing.

Applying metal contact material on means that the metal contact may be formed directly on the cleaned SiC surface area in which the Ohmic contact shall be prepared or may be formed directly above the SiC surface to be metallized as Ohmic contact. Intermittent layers or intermittent surface particles between the SiC surface area and the Ni metal contact material should be cleaned off before the application or should be present in low amounts only.

The method may further comprise annealing the SiC/Ni metal stacks to form Ohmic contacts at the interface between the SiC and the nickel metal. Annealing in this regard means heating the metal contact material layers or films to a temperature and over a period of time sufficient to generate a Ni/SiC contact with Ohmic behavior.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other, instead emphasis being placed upon illustrating the principles of the disclosed subject matter. Like reference numerals designate corresponding similar parts. The features of the various illustrated examples can be combined unless they exclude each other. Examples are depicted in the drawings and are detailed in the description which follows.

FIG. 1 illustrates process steps of a method of forming a SiC wafer in line with a general concept of the present description.

FIG. 2 illustrates the manufacturing of SiC wafer in line with a first embodiment.

FIG. 3 illustrates the manufacturing of SiC wafer, especially optional post-processing steps, in line with a further embodiment.

FIG. 4 illustrates the manufacturing of SiC wafer in line with a second embodiment.

### DETAILED DESCRIPTION

In the following detailed description, semiconductor devices are based on silicon carbide, a material having potential for high-temperature, high-frequency, and radiation hardened applications. SiC is a wide-bandgap semiconductor material suitable for semiconductor devices with specific dielectric gate structures including diodes, metal oxide semiconductor field-effect transistors (MOSFETs), junction field-effect transistors (JFETs), or insulated gate bipolar transistors (IGBTs), for example. Any other semiconductor devices with a dielectric gate structure are included in the general concept of the present disclosure even if they are not literally mentioned herein. Many device types based on SiC material have the electric current flowing through the base material towards the metallized frontside or backside (e.g. the source or the drain of a MOSFET device or one of the electrodes of a diode). A proper metallization with a good adhesion to SiC allows to achieve a good electrical contact, especially Ohmic contact, during the annealing process after contact metal deposition.

The semiconductor devices may be manufactured from semiconductor substrates wherein the substrate shapes and sizes can vary and include commonly used round wafers of different sizes, for example, between 50 to 450 mm in diameter. Any other semiconductor substrate forms and sizes may be used instead of the exemplified round wafers commonly used.

In line with the description herein, a semiconductor substrate may generally be any semiconductor substrate comprising a SiC body at its surface, for example, in the form of a SiC-based substrate or as an epitaxy layer on a substrate of any material suitably used as semiconductor material for microelectronic devices. Generally, the SiC wafer with those device structures may be one with sidewall and bottom contact to p and n type SiC onto which a frontside contact silicide to either one or both of p and n type SiC shall be generated.

According to a first embodiment of the method of forming a SiC wafer the semiconductor substrate comprising silicon carbide at a surface thereof may start from a SiC wafer. How the SiC wafer is obtained is not important for the method described herein and any common preparation method can be used for this preliminary step. The thin SiC wafer to be treated in line with the method described herein is then treated by a preclean comprising at least a hydrogen plasma treatment. Hydrogen plasma can be a pure H₂ plasma or a mixture of H₂ with other gases, e.g. carrier gases. An ex-situ or in-situ H₂ plasma preclean may in most cases sufficient to remove the particles and contaminants present at the surface of the SiC substrate before the metal contact material is applied. In-situ hydrogen plasma may also be used in volume production without breaking the vacuum before the metal contact deposition. No time coupling, for example, is needed when working in-situ.

In some embodiments, the SiC surface may be cleaned by the hydrogen plasma alone or in combination with a HF preclean. HF preclean in addition to the hydrogen plasma may be used, for example, if a resist pattern is used for patterning the front side or back side surface of the SiC wafer as will be described later in greater detail. A patterning of the surface by photoresists may be suitably used to create a topology with negative slope so that when a meal is deposited on the wafer there is a disconnection between the top metal and the bottom metal in the contact region, for example. In some examples, the resist may be removed and the top metal lifts off leaving behind only bottom metal in the contact regions, for example. A silicide is formed with the remaining metal using high temperature processing in the following annealing step.

According to an embodiment, for example in the first embodiment described above, a nickel metal contact material may be applied on the cleaned surface area to form SiC/Ni metal stacks at the surface of or at least parts of the SiC substrate to be contacted. The metal is deposited on those parts of the SiC substrate on which metallization should be carried out for forming Ohmic contacts. Thus, the deposited metal is later reacted with SiC to form a silicide as interlayer for Ohmic contacts at the surface of SiC substrates. The silicide interlayer produced later by the annealing reaction improves the contact resistance (Rₒₙ) in the manufactured SiC/NiSi/Ni stacks.

In some embodiments, the nickel metal contact material may be a pure nickel metal or a nickel-based alloy. Alloying metals may be titanium or aluminum. Alternatively, nickel silicide may suitably be used as contact material.

In some embodiments, the applied metal contact material, for example, the nickel metal contact material, and the SiC substrate are heated to form a silicide, especially, a NiSi layer, at the intermediate layer of the SiC/Ni metal stack. In this annealing step, any high temperature processing using a temperature and time suitable for silicidation reaction between the SiC substrate surface and the deposited nickel metal contact can be used. Suitable annealing processes are known in this filed. Higher annealing temperatures may be needed if the Ni to SiC interface is of poor quality. Hydrogen plasma preclean could therefore enable the use of lower annealing temperatures to form the silicided contacts.

The substrate may be a SiC substrate comprising a front surface on or in which semiconductor elements are formed and a back surface which faces the front surface. For example, the Sic substrate may be used for preparing a semiconductor device including the SiC substrate as body region in which a drift region of a first conductivity type, a body region of a second conductivity type, and a source region of the first conductivity type are provided. Additionally, the body region may be provided with a gate structure comprising a gate electrode and a gate dielectric that isolates the gate electrode form the SiC body, wherein the gate structure may be disposed adjacent to the source region, the body region, and the drift region.

A drift region of a first conductivity type may be prepared by doping the respective region of the SiC body. In the same way, the source region may be prepared by doping the respective region of the SiC body. Depending on the type of the semiconductor device, first conductivity type may mean a doping with negative charge carriers and a second conductivity type may mean a doping with positive charge carriers (holes), for example, or vice versa. For each embodiment the general conductivity of the first or second type shall be the same, however, different charge carrier concentrations may be used within one conductivity type respectively, also known as n+ or n-or p+ or p-doped substrates or active regions.

The SiC body may include a well region with higher doping levels for increasing the charge transfer through the conductivity channel. Furthermore, the SiC body may include SiC epitaxial layers of the same conductivity type as the drift region of the SiC body. Moreover, a drain electrode may be provided adjacent to the drift region of the SiC body and/or the SiC epitaxial layers. Generally, the herein described dielectric structures may be used in n-channel or p-channel transistors.

The present disclosure encompasses planar or trench semiconductor devices comprising a common gate structure, for example, based on SiO₂ as gate dielectric, and a source metal that electrically contacts the source region, wherein an interlayer dielectric isolates the gate electrode from the source metal. The source electrode, for example, may be made of or comprises nickel metal contacts as described herein in detail. Of course, any other electrodes may be prepared according to the methods described herein.

Generally, planar type semiconductor devices can include a gate structure which may extend between the source region and the drain region. The gate structure may be disposed on a portion of the source region and a portion of the drain region. In some examples, a first source region and a second source region may be provided within one pnp junction as described herein. Then, the gate structure may be disposed on the SiC body and may be disposed on a portion of the first source region and on a portion of the second source region.

In trench semiconductor devices, the gate structure comprises trench sidewalls and trench bottom regions on which the nickel-based metal contacts in line with the present description are to be generated. Due to the specific form of the trench-based gate structures, the SiC substrate regions at the side wall and the bottom of each trench may have different crystal planes at the surfaces of the SiC substrate. The different crystal planes may silicide differently and may be differently reactive to the precleaning. Using a hydrogen plasma based precleaning may be advantageous in simultaneously cleaning the different exposed planes in a trench like gate structure. The reason may be that hydrogen plasma without bias is isotropic. Thus, it will work on a trench sidewall because there is no directionality. Thus, different to wet chemical cleaning methods, such as HF cleaning, or directional sputtering cleaning methods, e.g. with gases such as inert gases, the hydrogen plasma precleaning of the SiC substrate may result in cleaner surfaces at the trench sidewalls as well as the bottom regions of the trenches.

HF etching generally is a wet chemical cleaning method. If wet chemical treatments such as HF etching is used for cleaning narrow and/or deep trench structures, the chemicals must enter the trench structures. If chemicals do enter the trench, it can then be difficult to get the chemicals out of high aspect ratio trenches and there is a risk of leaving behind undesirable residues in the trenches. Moreover, during wet etching, gas may be generated, and gas bubbles could be trapped in the trenches. Thus, reliable results may not easily be achieved using wet chemical etching alone. Therefore, at least one hydrogen plasma cleaning step may be applied before the nickel metal contact is applied onto the SiC substrate surfaces to be contacted. Wet chemical cleaning methods may be more preferably used in planar type semiconductor devices or at the backside surface of the SiC substrate which usually is not structured like the frontside. Sometimes, also the backside comprises structured surface areas so that hydrogen plasma cleaning as described herein may be advantageously used in these kinds of SiC substrates as well.

Sputtering of gases such as Ar or other noble or inert gases may be used together with the hydrogen plasma cleaning or as an additional cleaning step, for example, before the hydrogen plasma cleaning as described herein. In trench structures sputtering cleaning techniques have some problems to reach any region of the trenches because of the directionality of the sputtering method. Sputtering also may mean there is a risk of crystal damage and additionally a risk of knocking into the lattice any surface contamination. The bias voltage used to accelerate the atoms to cause it to sputter the SiC surface may clean some parts of the trenches better than others. Therefore, a hydrogen plasma cleaning as described herein may overcome the problems with the conventional cleaning methods.

In some embodiments of the manufacturing method described herein, the front surface is cleaned, and contacts are formed at surface areas at which SiC is directly present at the surface of the substrate. As described before, at least a hydrogen plasma cleaning is used to clean the source or drain regions of the SiC substrate in which the metal contact material shall be applied. The gate regions which generally are provided with a gate dielectric, e.g. a SiO₂ based layer or structure, may be cleaned as well. When depositing the nickel metal as contact material, it can be applied to any regions, for example, by sputtering the nickel metal material in the form of a thin layer. During the annealing step, however, the silicide reaction takes place only at those regions at which SiC is directly present at the surface, that means, the source and drain regions of the SiC body, for example. Generally, at those regions covered by a dielectric layer, especially, an oxide layer, generally no silicide reaction takes place or silicide in an insufficient amount is formed at those oxide surfaces by the annealing process only.

According to some embodiments, the manufacturing of Ohmic contacts is carried out at SiC surface areas, for example, at the frontside of a SiC substrate, wherein the SiC surface areas comprise n-or p-doped SiC substrates. Such n-doped or p-doped SiC substrates may be source or drain regions of the frontside of a planar or trench-based semiconductor device, for example. Thus, source and drain metallization with good Ohmic frontside contact silicide can be realized in a simple method with a few steps only. Compared to commonly used NiAl processing for Ohmic contact formation, the herein described methods have a reduced system complexity. Moreover, Al interaction complications can be avoided as Al generally is not present in the system when using generally pure Ni process techniques. The contact physics is easier to understand and to predict as it is a less complex Ohmic contact system based on NiSi interlayer formation only. In some examples, improved Ohmic frontside contacts with better Rₒₙ values have been generated. The contact resistance in n-doped contact regions were comparable or even better compared to NiSi contacts with NiAl processing technics. In some examples, Ron values could be improved by about 10%. In p-doped contact regions, an improvement by about 20% could be achieved. Thus, Al for NiSi formation is not needed for achieving good p-or n-type contacts if using the method as described herein. Even though the effects have been studied on frontside contacts, the method can easily be adapted and applied to backside contacts as well. Similar results as to the contact resistance are expected. In addition, an easier system and less complexity of the present method seems to be favorable for backside contacts as well.

As described above, the cleaning of the substrate surface is one of the main steps in the method described herein as contaminants on the substrate surface such as oxide particles or carbon particles, for example, may hinder a silicide formation at those areas. Thus, the substrate surface is cleaned or conditioned by the precleaning step using a hydrogen plasma. A HF preclean could also be used separately or in combination. In some embodiments, the cleaning of the substrate surface is carried out by a hydrogen plasma processing using a pure hydrogen atmosphere or an atmosphere comprising hydrogen in admixture with other gases. Such other gases may be carrier or inert gases such as noble gases, e.g. Ar, Xe, Kr. The hydrogen plasma may be used isotropic or as an anisotropic clean using a bias voltage. It may be suitable to use an isotropic plasma for cleaning trench-based structures, usually provided at the frontside of semiconductor device. As an isotropic hydrogen plasma has no directionality, trench like sidewall contact can be reliable cleaned even if the trench is a narrow and deep trench. Generally, hydrogen plasma can remove oxides, Si, and or carbon, or anything that reacts with hydrogen ions and radicles. If it doesn't react directly then it can be sputtered using a bias voltage and or sputter/carrier gas. In addition, the hydrogen plasma precleaning reduces defects on the SiC substrate surface, for example, defects on the contact sidewalls. Thus, a reliable and uniform deposition of the nickel metal contact material and a uniform annealing and silicide formation reaction can be achieved by the specific precleaning treatment. The hydrogen plasma additionally improves the wetting of the metal, reduces the dewetting of the metal on interlayer dielectric and SiC. Therefore, a more uniform thickness of the silicide interlayer after the annealing process can be achieved by reducing the defect density on the SiC substrate surface. More particularly, thin melting caused by the use of thin metal films and dewetting effects caused by surface properties at the interface may be improved by changing the properties at the interface during the hydrogen plasma precleaning. It has been noted that the behavior is more significant for some metals, especially, for nickel. NiAl, for example, has a better wetting ability compared to pure nickel metal. Therefore, the method as herein described may be used for preparing pure nickel contacts. Alternatively, nickel alloys with metals having a good wetting characteristic may be used. Examples of such alloys are nickel titanium alloy.

After the surface has been cleaned and is contamination and/or defect free, a protection by means of an interlayer dielectric (e.g. AlOₓ) is not needed. Therefore, in some embodiments of the method described herein, after the precleaning by hydrogen plasma, the nickel metal or nickel-based alloy is applied on the cleaned SiC surface by a deposition method selected of sputtering processes and/or vapor deposition processes, for example. The sputtering or evaporation process may generate a thin film layer on the substrate. The metal contact material may be applied in a thickness of about 10 to 200 nm, particularly, about 30 to 100 nm, more typically about 50 nm. As very thin nickel metal contact material layers may be suitable for being applied and annealed, it is possible that only a few contaminations, e.g. comprising carbon particles, are present at the metal contact surface after the annealing. Very thin layers of nickel or nickel-based metal contact layers may produce less or even no carbon contamination. Also, thinner metals mean less consumption of the SiC in the silicide reaction. It can be suitable to control the depth of silicidation, e.g. for contacting at the implant peaks. Therefore, it is preferred to apply the nickel metal as thin as possible on the SiC substrate.

After the application of the nickel contact material, the method encompasses the step of at least heating the SiC/Ni metal generated at least at those parts of the SiC substrate surface in which Ohmic contact shall be generated. The annealing may comprise a rapid thermal processing (RTP), a high temperature oven process, or a laser thermal annealing at temperatures suitable for melting the thin nickel metal layer at least at the surface to the SiC substrate, thus enabling the formation of a silicide (NiSi) at the interface between SiC substrate and nickel metal contact layer. When applying a rapid thermal processing (RTP), suitable temperatures may be 450° C. or higher, more preferably higher than 550° C. Suitable annealing temperature ranges are between 500 and 1000° C. As the thickness of the applied nickel metal contact layer may be less than in commonly used methods, for example those using NiAl alloys, lower RTP temperatures can be enabled. Lower temperatures may cause an improved silicide formation. The time may be a factor when using lower temperatures. Therefore, it may be preferable to use a longer RTP process time instead of increasing the annealing temperature.

Alternatively, other annealing methods than RTP may be used. Exemplified annealing methods may encompass oven or furnace heating or laser thermal annealing, for example. The RTP and/or the other annealing methods may be combined or applied in one or more separate steps. In some examples, two RTP steps, optionally with a metal etch between the two steps, may be applied. As will be explained later, the metal etching or a plasma etching may be applied to eliminate oxides or carbon contaminations at the surface of the NiSi layer obtained. The etching may also be used to remove unreacted metal and/or alloy which is in excess present on the dielectric layers for example. This allows the structuring of the silicided metal without the need for a lift off photo resist type method, for example. In some embodiments, the second RTP step may be used to change the phases of the silicided metal. Some phases produce better contacts than others and the second RTP step may be suitably used to get to the desired phase. An intermediate etching of the obtained contamination particles or layers may improve the reliability of the semiconductor device and/or the contact resistance of the obtained nickel contacts.

Some embodiments of the method described herein may comprise a step of removing contaminants and/or unreacted Ni metal from the SiC/Ni metal stacks after the annealing. Metal etching techniques or oxygen plasma treatments may be used as post treatment after the first RTP. Some embodiments may further comprise an oxygen plasma processing of the nickel metal contact material. Such oxygen plasma processing may be one or more O₂ flash treatments as used in common NiAl based contact processes may be used herein as well, if needed at all.

After the removing of contaminants and/or unreacted Ni metal in the afore-mentioned post-processing, the method may further comprise an additional thermal annealing processing. This can be a second RTP or any other heat treatment, while rapid thermal processing techniques are preferred.

Herein described is also a SiC wafer comprising a silicon carbide (SiC) semiconductor substrate and a Ni metal contact layer at its main surface, manufactured by any of the aforementioned described methods wherein the Ohmic contact is provided by a nickel silicide layer formed by the annealing step. Such SiC wafers with frontside and/or backside Ohmic contacts as described herein may be the basis of semiconductor devices with different functionality. The pure nickel contacts on SiC with a thin silicide layer (NiSi) may be useful for scaling down the device structures while maintaining or improving the reliability of the contacts and/or the contact resistance at the same time, e.g. compared to contacts using NiAl based contacting processes. Fewer steps, easy manufacturing, reducing contaminations, and so forth may be the main advantages of the methods and semiconductor devices described herein.

In the following, two exemplified variants of the method will be explained with reference to the attached drawings in detail.

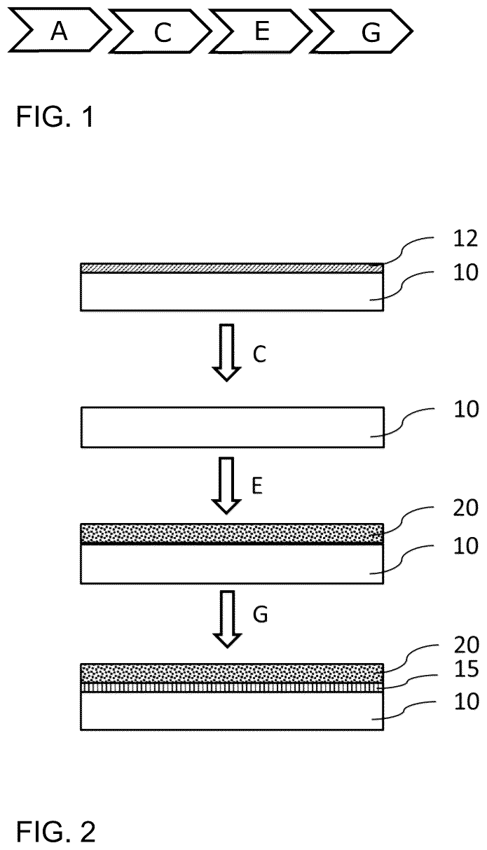

In the first example of the method of forming a semiconductor device shown in FIGS. 1 and 2, a semiconductor substrate consisting of or at least comprising SiC at regions to be contacted may be formed by any common method. The step of forming a semiconductor SiC substrate is shown as step A in FIG. 1. The SiC substrate 10 may be manufactured by providing different doped device structures in or on the surface of the SiC wafer. Thus, a planar type MOSFET may be produced in the following steps. The thus prepared frontside surface of the SiC substrate may optionally be precleaned by a wet chemical cleaning step, for example using HF etching for reducing most of the contaminants such as oxide particles or carbon containing clusters, which are on top of the SiC substrate 10 in the area 12. After or at the same time of the optional precleaning step (not shown in the FIG. 1), the SiC substrate comprising at least SiC at the surface or at least parts of the surface have been provided for the method as described herein. Thereafter, a cleaning (step C) may be carried out using a hydrogen (H₂) plasma atmosphere. This cleaning step allows to further reduce the amount of carbon clusters or oxide particles or other contaminants remaining in the area 12 above the substrate surface to be contacted. Additionally, the hydrogen plasma cleaning may reduce defects at SiC substrate surface areas to be contacted. This is assumed to be a chemical interaction or reaction with the Si and/or C atoms at the SiC surface. One assumption is that dangling bonds will be saturated by the hydrogen plasma. Generally, those parts of the SiC substrate surface already provided with other device structures, such as interlayer dielectric layers, for example, may be cleaned as well, but no significant reductions of the layer thicknesses of these device structures already included in the frontside of the SiC substrate may be observed.

The cleaning treatment in a hydrogen plasma atmosphere or hydrogen containing plasma atmosphere (Step C) may be carried out at a time, temperature, and pressure that is adjusted to clean or to condition the surface without major SiC substrate surface rearrangements.

During and after the cleaning of the substrate surface, it may be preferred to avoid any oxidizing atmosphere before the next process step is carried out. Therefore, methods without changing the working embodiment would be preferably used to avoid formation of native oxides (SiOxCy) or carbon clusters or other unwanted contaminants on the cleaned substrate surface. Other as in NiAl processes commonly used, the formation of a passivation layer on the cleaned surface is not necessary. Therefore, a lower number of steps makes the present method favorable over conventional manufacturing processes.

Generally, the method as described in this first embodiment encompass depositing a nickel metal contact material or nickel-based alloy contact material on or above the cleaned SiC substrate surface at least at parts to be contacted (Step E in FIG. 1). Above does mean in this regard the direct deposition of the contact material 20 on the SiC substrate surface 10 or the deposition via an intermediate layer such as a passivation layer, if present. As pure Ni does react with SiC but not with native oxides or carbon clusters, generally the nickel metal contact material 20 may be directly deposited on the SiC substrate surface 10 by any sputtering or evaporation method commonly used in this technical field. The application of the nickel metal contact material 20 on the SiC substrate surface may be carried out in an inert or non-oxidizing atmosphere (in situ or ex-situ process). If technically possible and suitable, the whole process can be performed without exposing the processed surfaces to an oxidizing atmosphere at least util the nickel metal contact material has been applied onto the substrate After the application of the nickel metal contact material 20 on the SiC substrate 10 (Step E), the stack of SiC and Ni is heated to a temperature of at least 450° C. over a sufficient time allowing at least partly melting the nickel metal component and generating a silicide, e.g. NiSi, at the interface between the SiC substrate 10 and the nickel metal contact material 20 (Step G). The thus obtained thin NiSi or silicide contact layer 15 is assumed to improve the contact resistance of the manufactured contact at those areas in which pure nickel or nickel-based alloy is in direct contact with the SiC substrate 10. At areas where an ILD (e.g. oxide) device structure has been provided before, no silicide reaction takes place and pure nickel metal contact material remains at the surface thereof. At the areas where the ILD is not provided and the SiC substrate is exposed, the silicide reaction takes place and generates the nickel Ohmic contact.

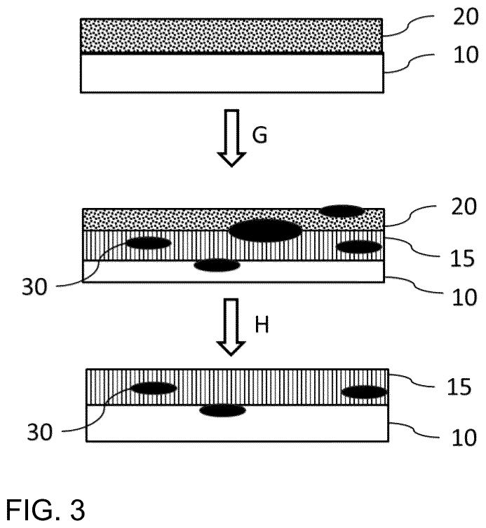

As shown in FIG. 3, the silicide reaction (Step G) may generate a stack of SiC substrate 10, nickel silicide 15 (e.g. NiSiₓ), and unreacted nickel metal 20. During the annealing, carbon clusters 30 generated from the SiC decomposition during the silicide reaction may be generated within the silicide layer, at the interface between the SiC and NiSi, or at the surface of the nickel metal layer 20. Those carbon clusters may be removed in step H by an O₂ flash procedure. Especially, those carbon clusters 30 at the surface of the metal or within the unreacted metal layer may be removed by this post-processing. Alternatively, or in addition, a wet etching (e.g. Piranha etch) may be used in step H for removing the unreacted nickel metal 20 including the carbon clusters 30 within one step, thus remaining a silicide surface as contact. Optionally, a second RTP may be carried out for improving the Ohmic contact. Similar temperatures and conditions as in the first RTP can be applied here.

Not only unreacted material at the contact sides can easily be removed after the annealing has been finished, but also unreacted metal (not shown in the Figures) on top of oxides or other layers not forming any silicide may then be removed by a wet chemical etching method, for example, a Piranha or Karo etch or similar, leaving the silicide behind in contact areas.

This herein called “lift off free” variant of the method described herein may be preferred because no metal structuring during this process is needed because of the selectivity of the silicide reaction. In addition, no photoresists (resins etc.) are needed in this variant. Thus, no resist coating and removal steps are needed and less contaminations are produced by this method. Further advantages are an improvement of the contact performance because the fully covering of the ILD with metal during the annealing of the substrate stack may prevent out diffusion of dopants to the NiSi.

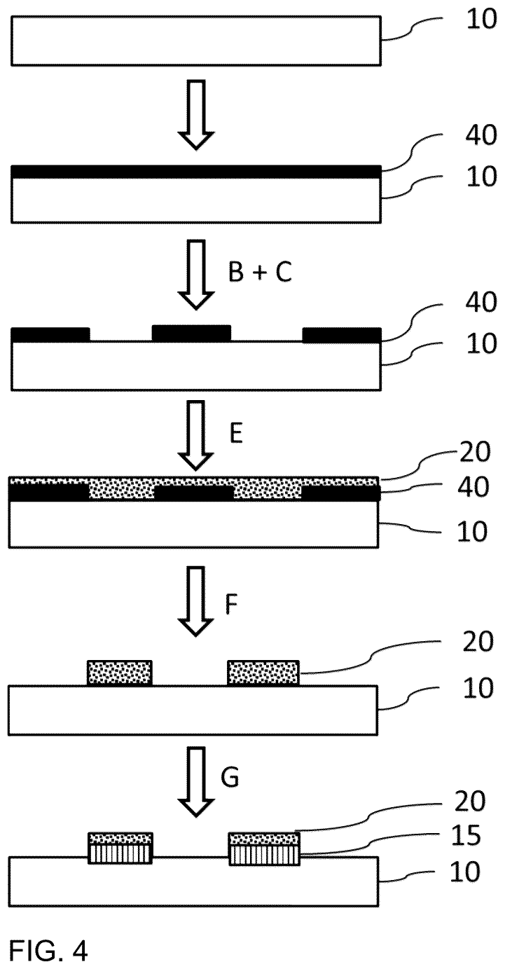

Now referring to FIG. 4, a further variant is the herein called “lift off” method using a photoresist 40 and ILD etching to create a topology with a negative slope on the SiC substrate surface 10. After the ILD etching, the SiC surface is cleaned by at least a hydrogen plasma cleaning (Step C) and, optionally, a HF etching (Step B) to remove resist material from contact areas of the substrate. When a nickel metal layer 20 is deposited on the wafer there is a disconnection between the top metal on the resist 40 and the bottom metal in the contact region at the exposed and cleaned SiC substrate 10 areas. The resist 40 is removed in step F, and the top metal lifts off while leaving behind bottom metal 20 in the contact region(s) only. A silicide is formed in step G by reaction between the SiC and the remaining metal 20, e.g. pure nickel metal or nickel-based alloy, using high temperature annealing (e.g. 450-1000° C.).

As has been shown in the above-described variants of the method, using pure nickel (e.g. purity higher than 99 % or even higher than 99.9 %) could eliminate the need for a post silicide metal etch because no metal residues remain on the substrate or the sidewalls of a trench. The hydrogen plasma cleaning also improves the wetting and pure nickel does not react or have a low reaction rate with potential contaminants, e.g. O, C, P containing particles or substances.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A method of manufacturing a silicon carbide (SiC) wafer comprising:
forming a substrate comprising SiC at one or more parts of a surface;
cleaning a surface area of the substrate by a hydrogen plasma atmosphere;
applying nickel metal contact material on the cleaned surface area to form one or more SiC/Ni metal stacks at the one or more parts of the surface; and
annealing the one or more SiC/Ni metal stacks to form Ohmic contacts at the interface between SiC of the one or more SiC/Ni metal stacks and nickel metal of the one or more SiC/Ni metal stacks.

2. The method of claim 1, wherein the substrate comprises a front surface on or in which semiconductor elements are formed and a back surface which faces the front surface.

3. The method of claim 2, wherein the front surface of the substrate is cleaned and contacts are formed at one or more surface areas at which SiC is directly present at the front surface of the substrate.

4. The method of claim 3, wherein the one or more surface areas comprise at least one of one or more n-doped SiC substrates or one or more p-doped SiC substrates.

5. The method of claim 1, wherein the cleaning of the surface area is carried out by a hydrogen plasma processing using at least one of a pure hydrogen atmosphere or an atmosphere comprising hydrogen in admixture with at least one of a carrier or inert gas.

6. The method of claim 1, wherein the nickel metal is applied by a sputtering process.

7. The method of claim 1, wherein the nickel metal is applied by a vapor deposition process.

8. The method of claim 1, wherein the annealing comprises a rapid thermal processing.

9. The method of claim 1, wherein the annealing comprises a high temperature oven process.

10. The method of claim 1, wherein the annealing comprises a laser thermal annealing.

11. The method of claim 7, wherein the rapid thermal processing is carried out at temperatures of 550°C or higher.

12. The method of claim 1, further comprising removing contaminants from the one or more SiC/Ni metal stacks after the annealing.

13. The method of claim 12, further comprising an additional thermal annealing processing after the removing of contaminants.

14. The method of claim 1, further comprising removing unreacted Ni metal from the one or more SiC/Ni metal stacks after the annealing.

15. The method of claim 14, further comprising an additional thermal annealing processing after the removing of unreacted Ni metal.

16. The method of claim 1, further comprising an oxygen plasma processing of the nickel metal contact material.

17. A method of manufacturing a silicon carbide (SiC) wafer comprising:
forming a substrate comprising SiC at one or more parts of a surface;
cleaning a surface area of the substrate by a hydrogen plasma atmosphere;
applying nickel metal contact material on the cleaned surface area to form one or more SiC/Ni metal stacks at the one or more parts of the surface; and
annealing the one or more SiC/Ni metal stacks to form one or more Ohmic contacts.

18. The method of claim 17, wherein the cleaning of the surface area is carried out by a hydrogen plasma processing using at least one of a pure hydrogen atmosphere or an atmosphere comprising hydrogen in admixture with at least one of a carrier or inert gas.

19. A method of manufacturing a silicon carbide (SiC) wafer comprising:
cleaning a surface area of a substrate by a hydrogen plasma atmosphere;
applying nickel metal contact material on the cleaned surface area to form one or more SiC/Ni metal stacks; and
annealing the one or more SiC/Ni metal stacks to form one or more Ohmic contacts.

20. The method of claim 19, wherein the cleaning of the surface area is carried out by a hydrogen plasma processing using at least one of a pure hydrogen atmosphere or an atmosphere comprising hydrogen in admixture with at least one of a carrier or inert gas.
